(19) United States
(12) Patent Application Publication
(10) Pub. No.: US 2012/0151301 A1
(43) Pub. Date: Jun. 14, 2012

(54) SEMICONDUCTOR MEMORY DEVICE

(75) Inventors: Tatsuo IZUMI, Yokohama-Shi (JP); Mitsuhiro Noguchi, Yokohama-Shi (JP)

(73) Assignee: KABUSHIKI KAISHA TOSHIBA, Minato-Ku (JP)

(21) Appl. No.: 13/176,030

(22) Filed: Jul. 5, 2011

(30) Foreign Application Priority Data
Dec. 10, 2010 (JP) 2010-275346

(51) Int. Cl. H03M 13/05; G06F 11/10

(52) U.S. Cl. 714/773; 714/763; 714/E11.034

(57) ABSTRACT

This memory includes: bit lines; word lines crossing the bit lines; a memory cell array including memory cells provided to correspond to intersections between the bit lines and the word lines, respectively. A sense amplifier is connected to the bit lines and detects data stored in the memory cells. A word line driver controls a voltage of the word lines. An error-correcting unit includes a first error-correcting circuit having a first error-correcting capability and a second error-correcting circuit having a second error-correcting capability. The memory cells connected to each of the word lines in the memory cell block constitute a page. The error-correcting unit drives one of or both of the first and second error-correcting circuits during a data read operation or a data write operation according to a step count which is number of times of stepping up the voltage of the word lines during the data write operation.

### CROSS REFERENCE TO RELATED APPLICATIONS

This application is based upon and claims the benefit of priority from the prior Japanese Patent Application No. 2010-275346, filed on Dec. 10, 2010, the entire contents of which are incorporated herein by reference.

### FIELD

The embodiments of the present invention relate to a semiconductor device.

### BACKGROUND

An EEPROM (hereinafter, also simply “memory”) such as a NAND flash memory uses ECCs (error-correcting codes) to improve data reliability. Normally, repetition of write and erase (hereinafter, also “W/E”) causes an increase of defective memory cells (hereinafter, also “fail bits”). An ECC circuit corrects these fail bits and can thereby increase an upper limit of a W/E count for a memory.

To increase the upper limit of the W/E count, it suffices to use an ECC circuit having a high error-correcting capability. Due to this, the reliability of the memory improves. However, the ECC circuit having a high error-correcting capability consumes much power. Furthermore, while the W/E count is still low, the error-correcting capability of the ECC circuit is often excessively high because of the small number of fail bits with respect to the capability. In this case, the ECC circuit having an excessively high error-correcting capability consumes more power than necessary.

### BRIEF DESCRIPTION OF THE DRAWINGS

FIG. 1 is a block diagram showing a configuration of a semiconductor memory device according to a first embodiment;

FIG. 2 shows an example of a partial configuration of the memory cell array 1;

FIGS. 3A and 3B are conceptual diagrams showing an error-correcting process using both the first and second error-correcting circuits;

FIG. 4 is a flowchart showing a data write operation performed by the memory device according to the first embodiment;

FIG. 5 is a flowchart showing a data read operation performed by the memory device according to the first embodiment;

FIG. 6 is a block diagram showing an example of a configuration of a semiconductor memory device according to a second embodiment;

FIG. 7 is a flowchart showing a data write operation performed by the memory device according to the second embodiment;

FIG. 8 is a flowchart showing a data read operation performed by the memory device according to the second embodiment;

FIG. 9 is a block diagram showing an example of a configuration of a memory device according to a modification of the second embodiment; and

FIG. 10 shows a data write operation according to the modification of the second embodiment.

### DETAILED DESCRIPTION

A semiconductor memory device according to an embodiment of the present invention includes: a plurality of bit lines; a plurality of word lines crossing the bit lines; a memory cell array including a plurality of memory cells provided to correspond to intersections between the bit lines and the word lines, respectively. A sense amplifier is connected to the bit lines and detects data stored in the memory cells. A word line driver controls a voltage of the word lines. An error-correcting unit includes a first error-correcting circuit having a first error-correcting capability and a second error-correcting circuit having a second error-correcting capability. A plurality of memory cells connected to each of the word lines in the memory cell block constitute a page. The error-correcting unit drives one of or both of the first and second error-correcting circuits during a data read operation or a data write operation according to a step count which is number of times of stepping up the voltage of the word lines during the data write operation.

Embodiments will now be explained with reference to the accompanying drawings. The present invention is not limited to the embodiments.

### First Embodiment

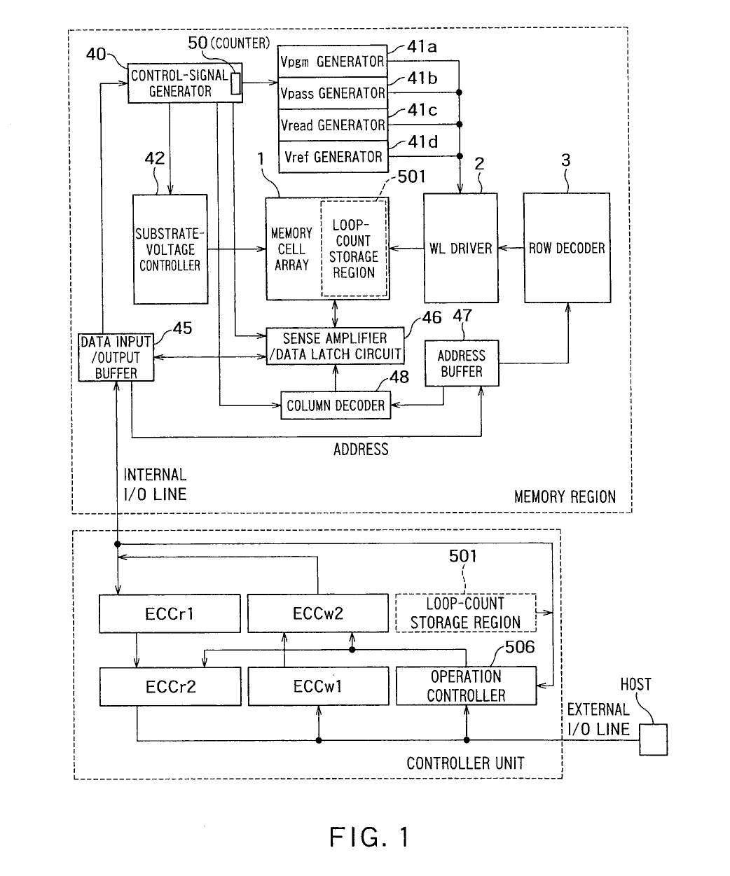

FIG. 1 is a block diagram showing a configuration of a semiconductor memory device (hereinafter, simply “memory device”) according to a first embodiment. It suffices that the memory device is configured to integrally encapsulate a memory unit and a controller unit with resin. The controller unit serves as an error-correcting unit and is configured to be able to control a plurality of memory units (memory chips).

Definitions are made as follows in relation to a memory unit. A memory block includes one or plural pages and indicates a unit of memory cells subjected to a simultaneous data erase operation. A page includes a plurality of memory cells connected to a certain word line (or data stored in those memory cells) and indicates a unit of memory cells subjected to a data write or read operation. The data erase operation, the data write operation, and the data read operation are also simply referred to as “erase operation”, “data write operation”, and “data read operation”, respectively. In a case of a flash memory cell including a charge storage layer, the memory cell block can be configured to include a plurality of pages and configure such that an erase operation is performed on a plurality of pages simultaneously or at once. For example, when memory cells are flash memory cells and an erase time for erasing data from memory cells corresponding to one page is longer than a write time for writing data to the memory cells corresponding to one page, the write time per block can be set almost equal to the erase time per block. As a result, it is possible to improve performances such as a write-data transfer rate and an erase rate from the perspective of a system.

The memory unit shown in FIG. 1 includes a memory cell array 1, a WL driver 2, a row decoder 3, a control-signal generator 40, a substrate-voltage controller 42, a data input/output buffer 45, a sense amplifier (including a data latch circuit) 46, an address buffer 47, a column decoder 48, a Vpgm generator 41a, a Vpass generator 41b, a Vread generator 41c, and a Vref generator 41d. The Vpgm generator 41a, the Vpass generator 41b, the Vread generator 41c, and the Vref generator 41d are also simply referred to as “generators”.

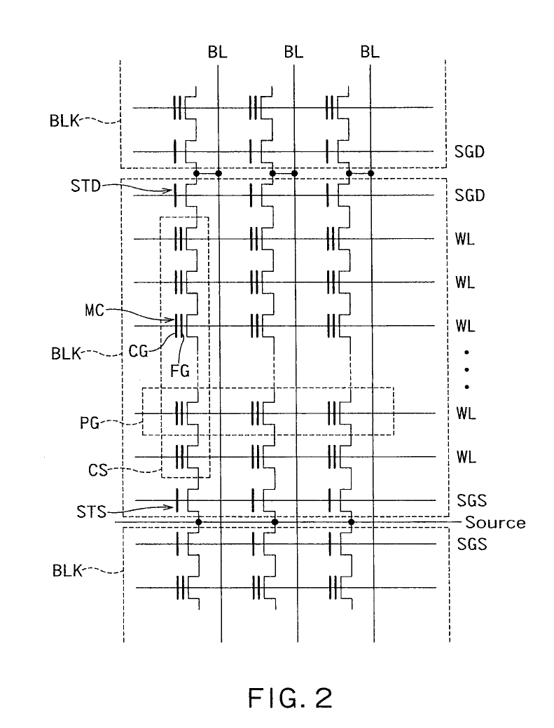

The memory cell array 1 is configured to include a plurality of memory cells MCs arranged two-dimensionally in a matrix. Detailed configurations of the memory cell array 1 are described later with reference to FIG. 2.

The sense amplifier 46 is connected to bit lines BLs and detects data in the memory cells MC via the bit lines BL during the data read operation. The sense amplifier 46 also serves as a data latch and functions to hold data during the data read or write operation. The sense amplifier 46 applies voltage to the bit lines BL according to the data held during the data write operation.

The column decoder 48 receives a column address signal from the address buffer 47, and decodes and outputs the column signal. The write data given to the data input/output buffer 45 can be thereby written to the memory cells MC connected to a desired bit line BL. Alternatively, data in the memory cells MC connected to the desired bit line BL can be read via the data input/output buffer 45 and an internal I/O line.

The address buffer 47 temporarily holds address signals stored in the data input/output buffer 45. The data input/output buffer 45 stores such signals as data, addresses, and commands received from each controller unit (controller chip).

The WL driver 2 is a switch circuit connected to word lines WLs and controlling voltages of the word lines WL during the read, write, and erase operations.

The row decoder 3 receives a row address signal from the address buffer 47, and decodes and outputs the row address signal. The WL driver 2 can thereby select a plurality of memory cells MC (a desired page) connected to a desired word line WL during the write or read operation.

The control-signal generator 40 receives commands from the data input/output buffer 45, and controls the voltage generators 41a, 41b, 41c, 41d, and 42 according to the respective commands.

The Vpgm generator 41a generates, for example, a write voltage Vpgm boosted from power supply voltage. The write voltage Vpgm is used for the memory cells MC selected during the write operation. The write voltage Vpgm is applied to, for example, control gates of the selected memory cells MC (selected word line WL). The write voltage Vpgm is, for example, equal to or higher than 10 volts (V) and equal to or lower than 30 V.

The Vpass generator 41b generates a write intermediate voltage Vpass. The write intermediate voltage Vpass is used for unselected memory cells MC during the data write operation. For example, the write intermediate voltage Vpass is applied to control gates of the unselected memory cells MC (unselected word lines WL) during the data write operation. The write intermediate voltage Vpass is, for example, equal to or higher than 3 V and equal to or lower than 15 V.

The Vread generator 41c generates a read intermediate voltage Vread. The read intermediate voltage Vread is used for the unselected memory cells MC during the data read operation. For example, the read intermediate voltage Vread is applied to the control gates of the unselected memory cells MC (unselected word lines WL) during the data read operation. The read intermediate voltage Vread is, for example, equal to or higher than 1 V and equal to or lower than 9 V. To sufficiently secure read current and suppress read-disturb, it is preferable to set the read intermediate voltage Vread higher by 1 V than an upper limit of a threshold voltage of the memory cells MC.

The Vref generator 41d generates a threshold-value determination voltage Vref. The threshold-value determination voltage Vref is used for the selected memory cells MC during the data read operation. For example, the threshold-value determination voltage Vref is applied to the control gates of the selected memory cells MC (selected word line WL) during the data read operation. The threshold-value determination voltage Vref is an intermediate voltage between threshold voltages of the memory cells MC storing mutually different logic data. For example, in a case of a binary memory, the threshold-value determination voltage Vref is set to an intermediate voltage between a threshold voltage distribution of the memory cells MC (“1” cells) storing data “1” and that of the memory cells MC (“0” cells) storing data “0”. In a case of a multi-valued memory, a plurality of threshold-value determination voltages Vref are set between adjacent-logic threshold voltage distributions, respectively. For example, in a case of a four-valued memory, three threshold-value determination voltages Vref1 to Vref3 are set between threshold voltage distributions of data “11” and data “10”, between those of data “10” and data “00”, and between those of data “00” and data “01”, respectively. Specifically, it suffices to set the threshold-value determination voltage(s) Vref in a range between −0.5 V and 5 V.

The substrate-voltage control circuit 42 controls a voltage of a p-silicon region (a p-well or p-silicon substrate) where the memory cell array 1 is formed. For example, the substrate-voltage control circuit 42 applies an erase voltage equal to or higher than 10 V to the p-silicon region during the erase operation.

The control-signal generator 40 controls the voltage generators 41a, 41b, 41c, 41d, and 42. Each of the voltage generators 41a and 41b, 41c, and 41d applies the necessary voltage to the selected word line WL via the WL driver 2 during the “data write”, “data read” or “data erase” operation.

The memory cell array 1 includes a loop-count storage region 501. The loop-count storage region 501 stores a step count (a write loop count) that is the number of write loops by which a word-line voltage is stepped up when writing data to each page in the memory cell array 1. The write loop count is also simply referred to as “loop count”.

Normally, in one write loop (one voltage application), threshold voltages of all the memory cells MC cannot shift into a target distribution. Therefore, the memory device steps up a voltage of the selected word line per write loop and repeats write loops. The threshold voltages thereby gradually rise and shift into a predetermined threshold range, and data is written to the memory cells MC. That is, a data write operation is completed by a plurality of write loops. The loop-count storage region 501 stores the write loop count during a data write operation per page.

The controller shown in FIG. 1 includes an operation controller 506, a first error-correcting encoding circuit ECCw1, a second error-correcting encoding circuit ECCw2, a first error-correcting decoding circuit ECCr1, and a second error-correcting decoding circuit ECCr2.

The first error-correcting encoding circuit ECCw1 and the first error-correcting decoding circuit ECCr1 constitute a first error-correcting circuit. The second error-correcting encoding circuit ECCw2 and the second error-correcting decoding circuit ECCr2 constitute a second error-correcting circuit. During the data write operation, the first error-correcting encoding circuit ECCw1 and the second error-correcting encoding circuit ECCw2 correct error bits in write data as first and second error-correcting circuits, respectively. During the data read operation, the first error-correcting decoding circuit ECCr1 and the second error-correcting decoding circuit ECCr2 correct error bits in read data as the first and second error-correcting circuits, respectively.

More specifically, the first error-correcting decoding circuit ECCr1 is connected to the memory unit via the internal I/O line, and receives read data from the memory cells MC during the data read operation. The error-correcting decoding circuit ECCr1 decodes the read data by a first error-correcting capability. The second error-correcting decoding circuit ECCr2 is connected between the first error-correcting decoding circuit ECCr1 and an external I/O line. The second error-correcting decoding circuit ECCr2 receives data from the first error-correcting decoding circuit ECCr1 and further decodes the data from the first error-correcting decoding circuit ECCr1 by a second error-correcting capability. Thereafter, the second error-correcting decoding circuit ECCr2 outputs the data decoded by the first and second error-correcting decoding circuits ECCr1 and ECCr2 to outside of the memory device via the external I/O line. Note that the first error-correcting decoding circuit ECCr1 outputs the decoded data when the operation controller 506 stops the second error-correcting decoding circuit ECCr2.

The first error-correcting encoding circuit ECCw1 is connected between the external I/O line and the second error-correcting encoding circuit ECCw2. During the data write operation, the first error-correcting encoding circuit ECCw1 receives the write data from outside of the memory device, and encodes the write data by a first error-correcting capability. The second error-correcting encoding circuit ECCw2 is connected between the first error-correcting circuit ECCw1 and the memory unit. The second error-correcting encoding circuit ECCw2 receives the data from the first error-correcting encoding circuit ECCw1 and further encodes the data received from the first error-correcting circuit ECCw1 by a second error-correcting capability. Thereafter, the second error-correcting encoding circuit ECCw2 transmits the data encoded by the first and second error-correcting encoding circuits ECCw1 and ECCw2 to the memory unit via the internal I/O line. Note that the first error-correcting encoding circuit ECCw1 outputs the encoded data when the operation controller 506 stops the second error-correcting encoding circuit ECCw2.

The error-correcting capabilities of the first error-correcting encoding circuit ECCw1, the second error-correcting encoding circuit ECCw2, the first error-correcting decoding circuit ECCr1, and the second error-correcting decoding circuit ECCr2 can be set either equal or different. For convenience sake, in relation to the data write operation, the error-correcting capabilities of the first and second error-correcting encoding circuits ECCw1 and ECCw2 are referred to as “first error-correcting capability” and “second error-correcting capability”, respectively. In relation to the data read operation, the error-correcting capabilities of the first and second error-correcting decoding circuits ECCr1 and ECCr2 are referred to as “first error-correcting capability” and “second error-correcting capability”, respectively.

The operation controller 506 is connected to the memory unit, the external I/O line, and the second error-correcting circuit (ECCr2 and ECCw2). The operation controller 506 controls operations performed by the first and second error-correcting circuits according to the loop count received from the loop-count storage region 501. The operation controller 506 can selectively drive either the first error-correcting encoding circuit ECCw1 or the second error-correcting encoding circuit ECCw2 or drive both of the first and second error-correcting encoding circuits ECCw1 and ECCw2 during the data write operation. The operation controller 506 can selectively drive either the first error-correcting decoding circuit ECCr1 or the second error-correcting decoding circuit ECCr2 or drive both of the first and second error-correcting decoding circuits ECCr1 and ECCr2 during the data read operation. In FIG. 1, the operation controller 506 can selectively stop the second error-correcting encoding circuit ECCw2 and the second error-correcting decoding circuit ECCr2, and selectively drive only the first error-correcting encoding circuit ECCw1 and the first error-correcting decoding circuit ECCr1.

Generally, the write loop count decreases according to an increase of the W/E count for the following reason. When the W/E count increases, then charge (such as electrons) trapped by a floating gate FG or a tunnel-gate dielectric film of the memory cell MC increases, and a threshold voltage of the memory cell MC before writing data thereto rises. Therefore, when the write loop count is high, it can be determined that the W/E count is low and that the number of error bits is relatively small during the write or read operation. Conversely, when the write loop count is low, it can be determined that the W/E count is high and that the number of error bits is relatively large during the write or read operation.

Accordingly, when the write loop count is equal to or higher than a predetermined value, the operation controller 506 selectively drives only the first error-correcting decoding circuit ECCr1 during the data read operation, and selectively drives only the first error-correcting encoding circuit ECCw1 during the data write operation. Further, when the write loop count is smaller than a predetermined value, the operation controller 506 drives both the first error-correcting decoding circuit ECCr1 and the second error-correcting decoding circuit ECCr2 during the data read operation, and drives both the first error-correcting encoding circuit ECCw1 and the second error-correcting encoding circuit ECCw2 during the data write operation. A predetermined value with which the write loop count is compared can be stored in a ROM (not shown) included in either the memory unit or the controller unit.

The control-signal generator 40 includes a counter 50 that takes the write loop count, and is configured to store information on the write loop count in the loop-count storage region 501 via the sense amplifier 46 after the write operation is finished.

Note that the counter 50 can be included not in the control-signal generator 40 but in the controller unit.

The write data is input to the controller unit from outside of the memory device according to the first embodiment via the external I/O line. The read data, that is, the data read from the memory cells MC is output to outside of the memory device via the external I/O line.

FIG. 2 shows an example of a partial configuration of the memory cell array 1. The memory cell array 1 is configured to include a plurality of the memory cells MC arranged two-dimensionally in a matrix. The word lines WL and the bit lines BL extend almost orthogonally. The memory cells MC are provided to correspond to intersections between the word lines WL and the bit lines BL, respectively. The memory cell MC is a FET (Field Effect Transistor) that includes a floating gate FG capable of storing charge and a control gate CG connected to one word line WL.

A plurality of the memory cells MC are connected in series and constitute a cell string CS. The cell string CS is connected to one bit line BL via a selection transistor STD on a drain side of the memory cells MC. The cell string CS is connected to a Source via a selection transistor STS on a source side of the memory cells MC. Control gates CG of the memory cells MC in the cell string CS are connected to the different word lines WL, respectively.

A plurality of the cell strings CS arranged in an extension direction of the word lines WL constitute a memory block BLK. As described above, the memory block BLK is the unit of the memory cells MCs subjected to the data erase operation. Furthermore, a plurality of the memory cells MC connected to a common word line WL constitute a page PG. As described above, the page PG is the unit of memory cells subjected to the data write or read operation.

As shown in FIG. 2, the selection transistor STD is controlled by a signal SGD and the selection transistor STS is controlled by a signal SGS.

As described above, the controller unit according to the first embodiment includes two types of error-correcting encoding circuits ECCw1 and ECCw2, the two types of error-correcting decoding circuits ECCr1 and ECCr2, and the operation controller 506.

Cyclic hamming encoding (or decoding) circuits or BCH (Bose-Chaudhutu-Hocquenghem) encoding (or decoding) circuits can be used as the error-correcting circuits ECCw1, ECCw2, ECCr1, and ECCr2. Alternatively, byte encoding (or decoding) circuits each operating on a code having 2r element, where r bits represents a code word, can be used as the error-correcting circuits ECCw1, ECCw2, ECCr1, and ECCr2. In the latter case, Reed-Solomon encoding (decoding) circuits can be used, for example.

Needless to say, the other encoding (decoding) circuits can be used as the error-correcting circuits ECCw1, ECCw2, ECCr1, and ECCr2. Examples of these other encoding (decoding) circuits include ECC circuits using BCH coding (decoding), majority logic coding (decoding), difference-set cyclic coding (decoding), LDPC (Low Density Parity Check) coding (decoding), and a combination of any of these schemes. Taking simplification of the configuration of the controller unit into account, the error-correcting circuits ECCw1, ECCw2, ECCr1, and ECCr2 are preferably cyclic encoding circuits each of which code (decodes) information bits in time series with a small circuit scale.

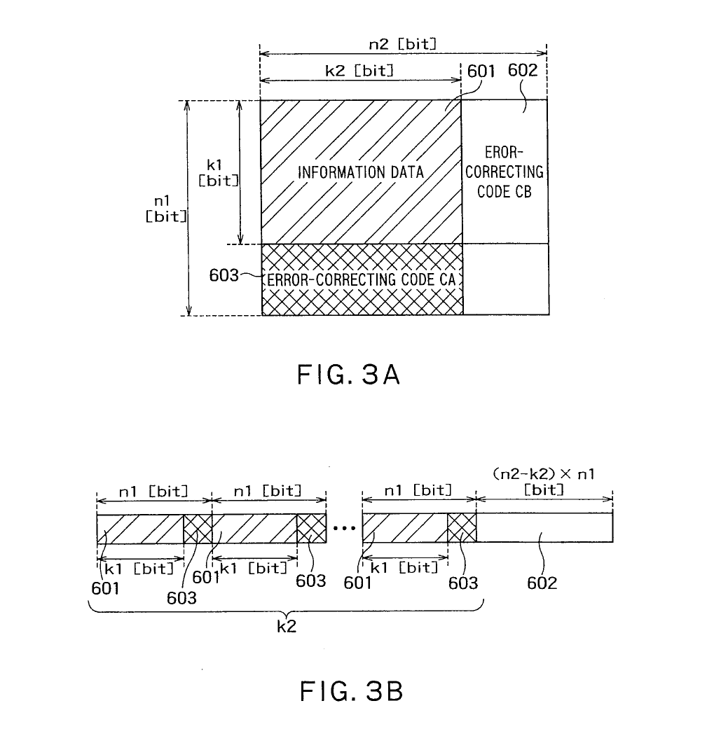

FIGS. 3A and 3B are conceptual diagrams showing an error-correcting process using both the first and second error-correcting circuits. For convenience sake, an error-correcting code of the first error-correcting circuits ECCr1 and ECCw1 is denoted by CA and that of the second error-correcting circuits ECCr2 and ECCw2 is denoted by CB. A code length of the error-correcting code CA is n1 and the number of information bits thereof is k1. A code length of the error-correcting code CB is n2 and the number of information bits thereof is k2. Both of the error-correcting codes CA and CB are linear systematic codes.

When error correcting is executed using both of the first error-correcting circuit ECCr1 (or ECCw1) and the second error-correcting circuit ECCr2 (or ECCw2), it is possible to create a product code or a concatenated code of the error-correction codes CA and CB.

For brevity of description, the product code is described below, but the same holds true for the concatenated code. A code length of a product code CA×CB of the error-correcting codes CA and CB is n1×n2 and the number of information bits thereof is k1×k2 as shown in FIG. 3A because the error-correcting codes CA and CB are linear systematic codes. Note that a minimum distance of the product code CA×CB is equal to a product of a minimum distance of the error-correcting code CA and that of the error-correcting code CB. Since an inter-code distance, that is, a distance between error-correcting t-bit codes is normally equal to or larger than (2t+1), an inter-code distance between the product codes CA×CB is larger than an inter-code distance between the error-correcting codes CA or CB. This means that the error-correcting capability using both of the first error-correcting circuit ECCr1 (or ECCw1) and the second error-correcting circuit ECCr2 (or ECCw2) is higher than that using the first or second error-correcting code. More specifically, using the known Reddy-Robinson decoding method with a minimum distance between the error-correcting codes CA assumed as dA and that between the error-correcting codes CB assumed as dB, it is possible to correct all of (dA×dB−1)/2 errors.

For example, the first error-correcting circuit arranges (k1×k2) pieces of information data 601 shown in FIG. 3A into k2 pieces of information data divided in units of k1 bits. The first error-correcting circuit encodes each piece of k1-bit information data using the error-correcting code CA. That is, the first error-correcting circuit adds the error-correcting code CA to each k1-bit information data. As a result, k2 pieces of first encoded data (601, 603) each having the code length of n1 are created. At this time, the number of entire bits of the error-correcting code CA (the number of bits of inspection data for first coding) is (n1−k1)×k2 bits corresponding to an area of 603 shown in FIG. 3A.

Next, the second error-correcting circuit encodes the first encoded data (n1×k2-bit data) while dividing the first encoded data in units of k2 bits. At this time, the second error-correcting circuit encodes each piece of the k2-bit first encoded data using the error-correcting code CB. That is, the second error-correcting circuit adds the error-correcting code CB to each k2-bit first encoded data and obtains second encoded data. The number of entire bits of the error-correcting code CB (the number of bits of inspection data for second coding) is (n2−k2)×n1 bits corresponding to an area of 602 shown in FIG. 3A. Therefore, as a whole, it is possible to create a product code of information data of (n1×n2) bits.

When the second encoded data is to be recorded in time series, it suffices to arrange and record the second encoded data one-dimensionally as shown in FIG. 3B. At this time, as shown in, for example, FIG. 3B, it suffices to arrange k2 pieces of n1-bit first encoded data in time series so as to correspond to each column shown in FIG. 3A and then to output the second error-correcting code CB of (n2−k2)×n1 bits.

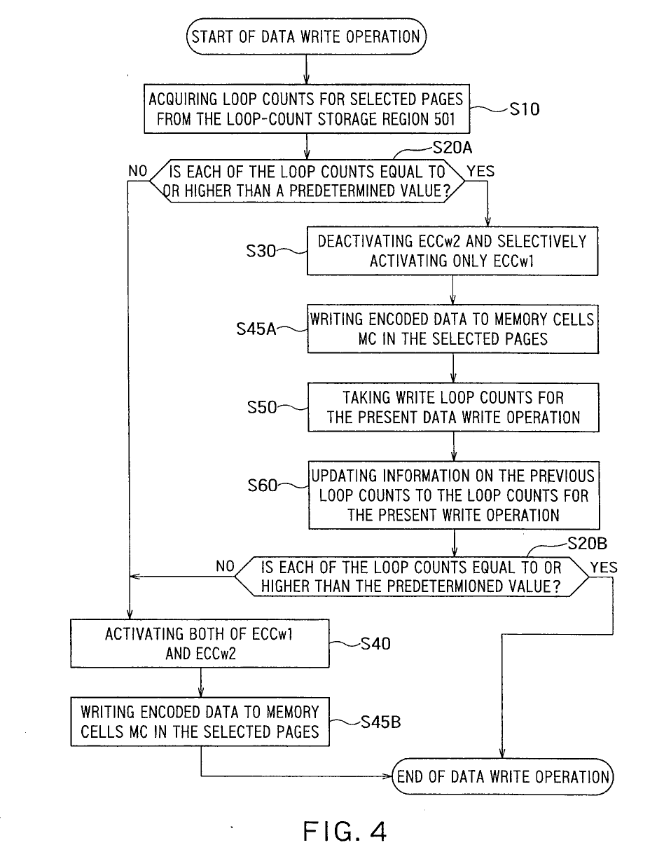

FIG. 4 is a flowchart showing a data write operation performed by the memory device according to the first embodiment. The loop-count storage region 501 has already stored therein a loop count per page for a previous write operation. When a data write operation starts, the operation controller 506 acquires loop counts for selected pages serving as a write target from the loop-count storage region 501 via the internal I/O line (S10). At this time, the loop counts read from the loop-count storage region 501 are those taken in the previously-executed write operation and stored in the loop-count storage region 501. The operation controller 506 reads the loop counts simultaneously with reading of data from the selected pages to prevent delay in the read operation.

The operation controller 506 determines whether each of the loop counts is equal to or higher than a predetermined value (S20A). When the loop count is equal to or higher than the predetermined value (S20A, YES), it can be estimated that the W/E count is low and that the number of error bits after the write operation is small. Therefore, the operation controller 506 stops (deactivates) the second error-correcting encoding circuit ECCw2 shown in FIG. 1 and selectively actuates (activates) only the first error-correcting encoding circuit ECCw1 shown in FIG. 1 (S30). It is thereby possible to eliminate an excessive error-correcting capability and to reduce the power consumption. It is also possible to reduce the time required for encoding and to realize a high-speed write operation.

Next, the encoded data is written to the memory cells MC in the selected pages (S45A). At this time, the operation controller 506 writes the loop counts to the loop-count storage region 501 to correspond to the respective pages. During this write operation, the counter 50 takes write loop counts for the present data write operation (S50). The loop counts taken in the present write operation are stored in the loop-count storage region 501 as the loop counts for the selected pages, respectively. That is, information on the previous loop counts is updated to the loop counts for the present write operation (S60). Thereafter, the operation controller 506 determines whether each of the loop counts is equal to or higher than the predetermined value (S20B). When the loop count is equal to or higher than the predetermined value (S20B, YES), it can be estimated that the W/E count is low and that the number of error bits after the write operation is small. Therefore, the data write operation is finished. At this moment, the operation controller 506 stops (deactivates) the second error-correcting encoding circuit ECCw2 shown in FIG. 1 and selectively actuates (activates) only the first error-correcting encoding circuit ECCw1 in step S30. As a result, the power consumption does not increase even when the data write operation is finished at this moment. When the loop count is lower than the predetermined count (S206, NO), it can be estimated that the W/E count is high and that the number of error bits after the write operation is large. Therefore, the operation controller 506 actuates (activates) both of the first and second error-correcting coding circuits ECCw1 and ECCw2 (S40). That is, the memory device operates similarly to a case where the loop count is lower than the predetermined value (S20A, NO). Operations after step S40 are described later in detail when a case where the loop count is lower than the predetermined value (S20A, NO) is described.

When the loop count is lower than the predetermined value (S20A, NO), it can be estimated that the W/E count is high and that the number of error bits after the write operation is large. Therefore, the operation controller 506 actuates (activates) both of the first and second error-correcting coding circuits ECCw1 and ECCw2 (S40). It is thereby possible to encode data with a high error-correcting capability such as that using the product code described with reference to FIG. 3. Thereafter, in the memory unit, the data encoded in step S30 or S40 is written to the memory cells MC in the selected pages (S45B). At this time, the operation controller 506 writes the loop counts to the loop-count storage region 501 to correspond to the respective pages. That is, the data latched by the sense amplifier 46 is encoded using the first and second error-correcting codes ECCw1 and ECCw2, the encoded data is latched again by the sense amplifier 46, and the latched data is written to the memory cell array 1. At that time, the operation controller 506 simultaneously writes the values stored in the counter 50 to the loop-count storage region 501. Note that the updated loop counts are used as information on the loop counts stored in the loop-count storage region 501. By storing these values, it is possible to accurately decode the data.

The predetermined value used for determination of the loop counts possibly differ according to the type, structure, production line and the like of the memory device and cannot be, therefore, identified unconditionally. For example, when the memory device is a NAND flash memory, the predetermined value used for the determination of the loop counts can be set to a numeric value from 5 to 50.

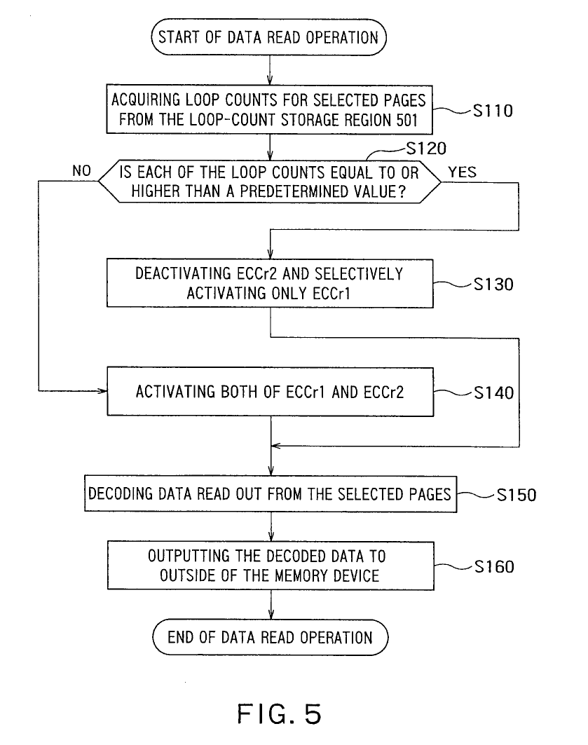

FIG. 5 is a flowchart showing a data read operation performed by the memory device according to the first embodiment. The loop-count storage region 501 has already stored therein a loop count per page for a previous program operation. When a data read operation starts, the operation controller 506 acquires previous loop counts for selected pages serving as a read target from the loop-count storage region 501 simultaneously with reading of data from the selected pages via the internal I/O line (S110).

The operation controller 506 determines whether each of the loop counts is equal to or larger than a predetermined value (S120). When the loop count is equal to or higher than the predetermined value (S120, YES), it can be estimated that the W/E count is low and that the number of error bits is small in the read data. Therefore, the operation controller 506 stops (deactivates) the second error-correcting decoding circuit ECCr2 shown in FIG. 1 and selectively actuates (activates) only the first error-correcting decoding circuit ECCr1 shown in FIG. 1 (S130). It is thereby possible to eliminate an excessive error-correcting capability and to reduce the power consumption. It is also possible to reduce the time required for decoding and to realize a high-speed read operation.

When the loop count is lower than the predetermined value (S120, NO), it can be estimated that the W/E count is high and that the number of error bits is large in the read data. Therefore, the operation controller 506 actuates (activates) both the first and second error-correcting decoding circuits ECCr1 and ECCr2 (S140). It is thereby possible to encode data with a high error-correcting capability such as that using the product code described with reference to FIG. 3. Thereafter, the controller unit decodes the data obtained from the memory unit and read from the selected pages in step S130 or S140 (S150), and outputs the decoded data to outside of the memory device via the external I/O line (S160).

Note that the loop-count storage region 501 holds the loop counts for the selected pages until a write operation is executed. Therefore, the same loop counts are used until the write operation is executed.

The memory device according to the first embodiment decodes the data in the pages for which the write loop counts are high by a relatively low error-correcting capability, and encodes or decodes the data in the pages for which the write loop counts are low by a relatively high error-correcting capability. The memory device can thereby encode or decode data using the error-correcting capability suited for the W/E count or the number of fail bits. This contributes to eliminating an excessive error-correcting capability and to reducing the power consumption. Furthermore, this can contribute to accelerating the read operation and the write operation. The first embodiment can thereby realize both reduction in the power consumption and acceleration in operation.

The W/E count is generally managed per memory block or memory chip that is a unit of memory cells subjected to an erase operation. Therefore, when the error-correcting capability is changed according to the W/E count, the memory device needs change the error-correcting capability at least for every memory cell block.

On the contrary, the write operation is executed per page, and thus can be stored and managed per page. Therefore, the memory device can change the error-correcting capability in smaller units than those for the memory cell blocks. That is, the first embodiment can set the error-correcting capability in detailed memory units as compared with a management scheme using the W/E count. As a result, the memory device according to the first embodiment can further reduce the power consumption and improve the reliability.

The memory device according to the first embodiment can use the concatenated code similarly to the product code. For example, a Reed-Solomon code having 2³ elements can be used as the first error-correcting code CA and a BCH code having 2 elements can be used as the second error-correcting code CB. That is, the effects of the first embodiment can be ensured as long as ECCs are linear codes.

In the first embodiment, the loop-count storage region 501 is provided in the memory cell array 1. Alternatively, the loop-count storage region 501 can be provided in the other location of the memory unit or, as indicated by a broken line in FIG. 1, provided in the controller unit. Likewise, the counter 50 can be provided in a location other than the control-signal generator 40.

The first and second error-correcting decoding circuits ECCr1 and ECCr2 and the first and second error-correcting encoding circuits ECCw1 and ECCw2 can be arranged in the memory unit or in a host unit connected to the controller unit via the external I/O line and present outside of the memory device.

Further, not the values of the counter 50 but binary data defined as follows can be stored in the loop-count storage region 501. When the operation controller 506 actuates either the first or second error-correcting encoding circuit ECCw1 or ECCw2, “0” is stored in the loop-count storage region 501. When the operation controller 506 actuates both the first and second error-correcting encoding circuit ECCw1 and ECCw2, “1” is stored in the loop-count storage region 501. As a result, it is possible to improve reliability of data stored in the loop-count storage region 501. Besides, “1” data for preventing charge from being accumulated in the memory cells MC is stored in the loop-count storage region 501 when the reliability of the memory cells MC deteriorates. It is thereby possible to further improve the reliability of the data stored in the loop-count storage region 501.

### Second Embodiment

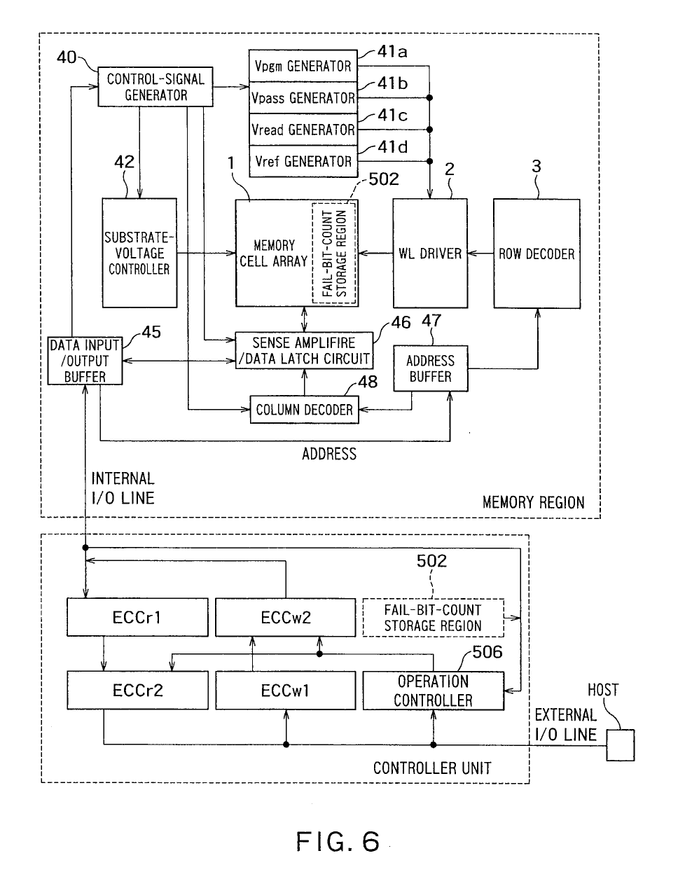

FIG. 6 is a block diagram showing an example of a configuration of a semiconductor memory device (hereinafter, simply “memory device”) according to a second embodiment. In the second embodiment, an error-correcting capability is changed based on the numbers of fail bits instead of the write loop-counts. The memory device according to the second embodiment can be configured similarly to that according to the first embodiment. Note that the memory device according to the second embodiment does not use the counter 50 shown in FIG. 1 and includes a fail-bit-count storage region 502 storing the numbers of fail bits instead of the loop-count storage region 501.

A fail bit means a bit indicating that data written to a certain page differs in logic from data read from the page. The fail-bit counts are confirmed by decoding redundant bits during a read operation. Accordingly, the fail-bit counts stored in the fail-bit-count storage region 502 are updated during a read operation and not updated during a write operation.

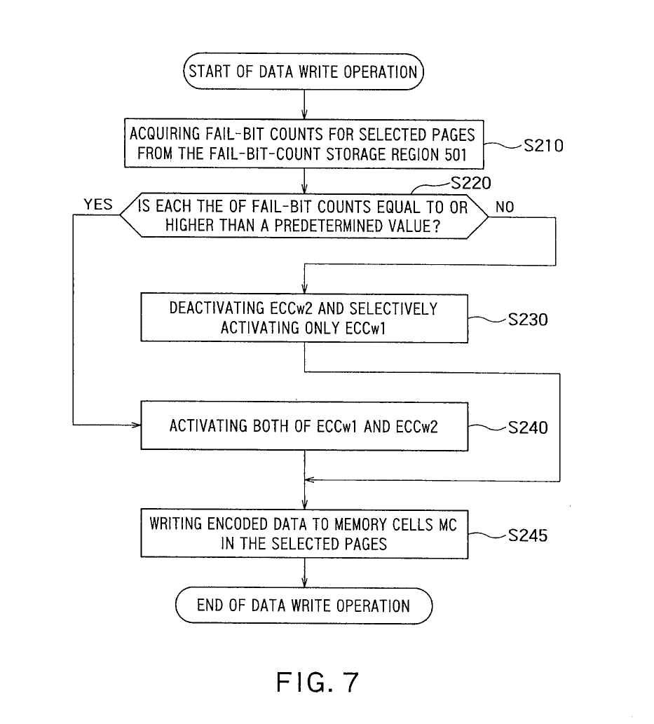

FIG. 7 is a flowchart showing a data write operation performed by the memory device according to the second embodiment. The fail-bit-count storage region 502 has already stored therein a fail-bit count per page for a previous write operation. When a data write operation starts, the operation controller 506 acquires fail-bit counts for selected pages serving as a write target from the fail-bit-count storage region 502 via an internal I/O line (S210). At the same time, data can be read from the selected pages.

The operation controller 506 determines whether each of the fail-bit counts is equal to or higher than a predetermined value (S220). When the fail-bit count is lower than the predetermined value (S220, NO), it can be estimated that the number of error bits after the write operation is small. Therefore, the operation controller 506 stops (deactivates) the second error-correcting encoding circuit ECCw2 shown in FIG. 6 and selectively actuates (activates) only the first error-correcting encoding circuit ECCw1 shown in FIG. 6 (S230). It is thereby possible to eliminate an excessive error-correcting capability and to reduce the power consumption. It is also possible to reduce the time required for encoding and to realize a high-speed write operation.

When the fail-bit count is equal to or higher than the predetermined value (S220, YES), it can be estimated that the number of error bits after the write operation is large. Therefore, the operation controller 506 actuates (activates) both of the first and second error-correcting coding circuits ECCw1 and ECCw2 (S240). It is thereby possible to encode data with a high error-correcting capability such as that using the product code described with reference to FIG. 3. Thereafter, in the memory unit, the data encoded in step S230 or S240 is written to the memory cells MC in the selected pages (S245).

The predetermined value used for determination of the fail-bit counts possibly differ according to the type, structure, production line and the like of the memory device and cannot be, therefore, identified unconditionally. For example, when the memory device is a NAND flash memory, the predetermined value used for the determination of the fail-bit counts can be set to a numeric value from 1 to 100.

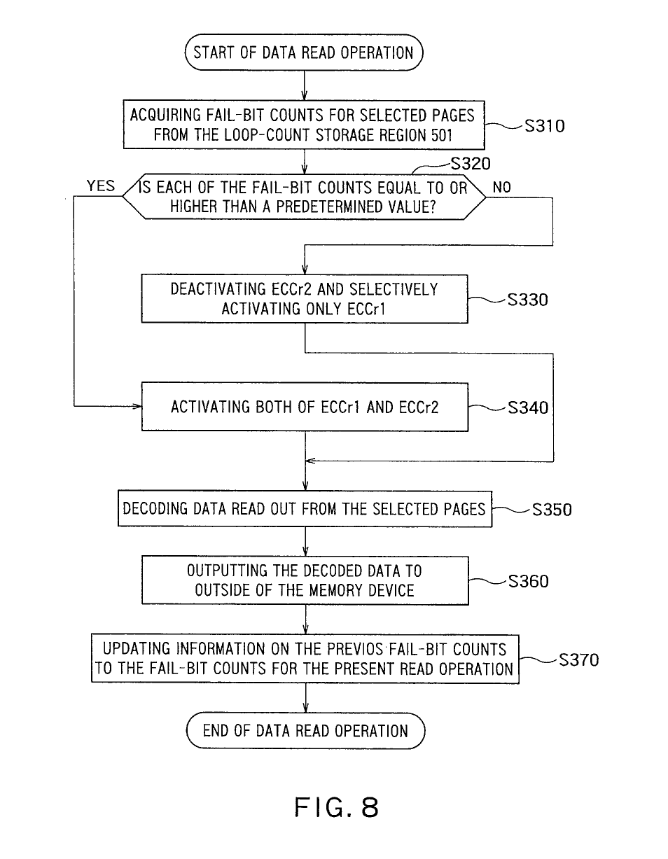

FIG. 8 is a flowchart showing a data read operation performed by the memory device according to the second embodiment. The fail-bit-count storage region 502 has already stored therein a fail-bit count per page for a previous read operation. When a data read operation starts, the operation controller 506 acquires previous fail-bit counts for selected pages serving as a read target from the fail-bit-count storage region 502 simultaneously with reading of data from the selected pages via the internal I/O line (S310).

The operation controller 506 determines whether each of the fail-bit counts is equal to or larger than a predetermined value (S320). When the fail-bit count is lower than the predetermined value (S320, NO), it can be estimated that the number of error bits is small in the present read data. Therefore, the operation controller 506 stops (deactivates) the second error-correcting decoding circuit ECCr2 shown in FIG. 6 and selectively actuates (activates) only the first error-correcting decoding circuit ECCr1 shown in FIG. 6 (S330). It is thereby possible to eliminate an excessive error-correcting capability and to reduce the power consumption. It is also possible to reduce the time required for decoding and to realize a high-speed read operation.

When the fail-bit count is equal to or higher than the predetermined value (S320, YES), it can be estimated that the number of error bits is large in the present read data. Therefore, the operation controller 506 actuates (activates) both the first and second error-correcting decoding circuits ECCr1 and ECCr2 (S340). It is thereby possible to encode data with a high error-correcting capability such as that using the product code described with reference to FIG. 3. Thereafter, the controller unit decodes the data obtained from the memory unit and read from the selected pages in step S330 or S340 (S350), and outputs the decoded data to outside of the memory device via the external I/O line (S360).

The fail-bit counts in the present read data is confirmed by the decoding in step S350. The fail-bit counts in the present read data are stored in the fail-bit-count storage region 502 to correspond to the respective selected pages. That is, information on the previous fail-bit counts is updated to the fail-bit counts for the present read operation (S370). The updated fail-bit counts are used during a next read operation.

The memory device according to the second embodiment can encode or decode data using the error-correcting capability suited for the fail-bit counts. Therefore, the memory device according to the second embodiment can use the error-correcting capability more suited for a present state of the memory device. Furthermore, the second embodiment can achieve effects identical to those of the first embodiment.

### Modification of Second Embodiment

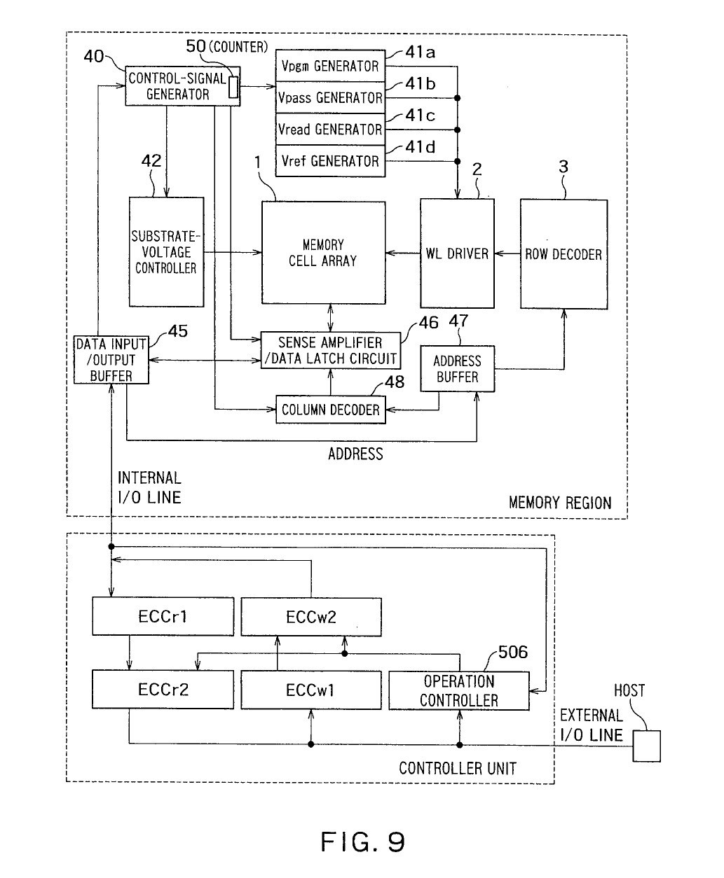

FIG. 9 is a block diagram showing an example of a configuration of a memory device according to a modification of the second embodiment. In the modification of the second embodiment, the memory device does not include the fail-bit-count storage region 502 as compared with the second embodiment. However, the memory device according to the present modification includes a counter 50 differently from the second embodiment and similarly to the first embodiment. Note that a fail-bit count is determined by causing the counter 50 to count fail bits for which data written to a certain page differs in logic from data read from the page. The fail-bit count is confirmed by decoding redundant bits during a read operation. Therefore, it is possible to dispense with the fail-bit-count storage region 502 and to downsize the memory cell array 1.

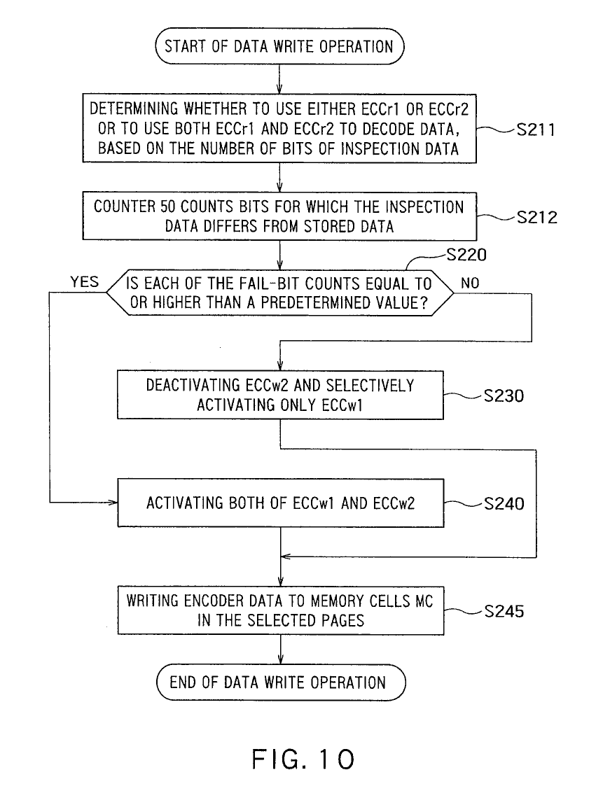

For example, FIG. 10 shows a data write operation according to the modification of the second embodiment. First, the operation controller 506 determines whether to use either a first error-correcting decoding circuit ECCr1 or a second error-correcting decoding circuit ECCr2 or to use both the first and second error-correcting decoding circuits ECCr1 and ECCr2 to decode data based on the number of bits of inspection data (S211).

Thereafter, the first or second error-correcting decoding circuit ECCr1 or ECCr2 or the both of the first and second error-correcting decoding circuits ECCr1 and ECCr2 calculate the inspection data, and the counter 50 counts bits for which the inspection data differs from stored data (bits different in logic value) (S212). Because subsequent operations of the present modification are identical to those of the second embodiment, explanations thereof will be omitted.

For example, the present modification is effective for page copying, that is, effective when data read from a certain page is copied to another page after reading the data. That is, it is possible to improve failure relief efficiency of the ECCs without need to provide the fail-bit-count storage region 502.

### Modification of First and Second Embodiments

In the first and second embodiments, the memory device determines the error-correcting capability per page. Alternatively, the memory device can determine the error-correcting capability per block. For example, when the write loop count for the selected page is lower than a predetermined value or the fail-bit count is equal to or higher than a predetermined value, the controller unit can use the high error-correcting capability shown in FIG. 3 for the entire memory cell block including selected pages.

Alternatively, the controller unit can use the high error-correcting capability shown in FIG. 3 for the entire memory cell block including the selected pages when an average value of write loop counts for all pages in the memory cell block is lower than a predetermined value or when an average value of fail-bit counts for all pages in the memory cell block is equal to or higher than a predetermined value.

In this case, despite change of the error-correcting capability per memory cell block, the memory device includes an error-correcting capability suited for the state of the memory device and possibly reduces the power consumption as compared with conventional techniques.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor memory device comprising:
a plurality of bit lines;
a plurality of word lines crossing the bit lines;
a memory cell array comprising a plurality of memory cells provided to correspond to intersections between the bit lines and the word lines, respectively;
a sense amplifier connected to the bit lines, and configured to detect data stored in the memory cells;
a word line driver configured to control a voltage of the word lines; and
an error-correcting unit including a first error-correcting circuit having a first error-correcting capability and a second error-correcting circuit having a second error-correcting capability, wherein
the memory cells connected to one of the word lines constitute a page, and
the error-correcting unit drives one of or both of the first and the second error-correcting circuits during a data read operation or a data write operation according to a step count, which is number of times of stepping up the voltage of the word lines during the data write operation.

2. The device of claim 1, wherein
the memory cell array includes a step-count storage region configured to store the step count of the voltage of the word lines during the data write operation, for each one of the page, and
the error-correcting unit selectively drives the first or the second error-correcting circuit during the data read operation or the data write operation when the step count is equal to or higher than a predetermined value, and drives both of the first and the second error-correcting circuits during the data read operation or the data write operation when the step count is lower than the predetermined value.

3. The device of claim 1, wherein
the error-correcting unit includes a step-count storage region configured to store the step count of the voltage of the word lines during the data write operation, for each one of the page, and
the error-correcting unit selectively drives the first or the second error-correcting circuit during the data read operation or the data write operation when the step count is equal to or higher than a predetermined value, and drives both of the first and the second error-correcting circuits during the data read operation or the data write operation when the step count is lower than the predetermined value.

4. The device of claim 2, wherein
the error-correcting unit writes data encoded by the first error-correcting circuit or reads data decoded by the first error-correcting circuit, when the step count is equal to or higher than a predetermined value, and
the error-correcting unit writes data encoded using a concatenated code used by the first error-correcting circuit and the second error-correcting circuit or reads data decoded using the concatenated code, when the step count is lower than the predetermined value.

5. The device of claim 3, wherein
the error-correcting unit writes data encoded by the first error-correcting circuit or reads data decoded by the first error-correcting circuit, when the step count is equal to or higher than a predetermined value, and
the error-correcting unit writes data encoded using a concatenated code used by the first error-correcting circuit and the second error-correcting circuit or reads data decoded using the concatenated code, when the step count is lower than the predetermined value.

6. The device of claim 1, wherein
the semiconductor memory device is NAND-type EEPROM.

7. A semiconductor memory device comprising:
a plurality of bit lines;
a plurality of word lines crossing the bit lines;
a memory cell array including a plurality of memory cells provided to correspond to intersections between the bit lines and the word lines, respectively;
a sense amplifier connected to the bit lines, and configured to detect data stored in the memory cells;
a word line driver configured to control a voltage of the word lines; and
an error-correcting unit including a first error-correcting circuit having a first error-correcting capability and a second error-correcting circuit having a second error-correcting capability, wherein
a plurality of memory cells among the memory cells constitute a memory cell block based on which data is erased, and the memory cells connected to each of the word lines in the memory cell block constitute a page, and
the error-correcting unit drives one of or both of the first error-correcting circuit and the second error-correcting circuit during a data read operation or a data write operation according to number of fail bits included in the page.

8. The device of claim 7, wherein the error-correcting unit selectively drives the first error-correcting circuit or the second error-correcting circuit during the data read operation or the data write operation, when number of fail bits in the page is lower than a predetermined value, and drives both of the first error-correcting circuit and the second error-correcting circuit during the data read operation or the data write operation, when the number of fail bits is equal to or higher than the predetermined value.

9. The device of claim 7, wherein the error-correcting unit writes data encoded by the first error-correcting circuit or reads data decoded by the first error-correcting circuit, when number of fail bits in the page is lower than a predetermined value, and
the error-correcting unit writes data encoded using a linear code used by the first error-correcting circuit and the second error-correcting circuit, or reads data decoded using the linear code, when the number of fail bits in the page is equal to or higher than the predetermined value.

10. The device of claim 8, wherein the error-correcting unit writes data encoded by the first error-correcting circuit or reads data decoded by the first error-correcting circuit, when number of fail bits in the page is lower than a predetermined value, and
the error-correcting unit writes data encoded using a linear code used by the first error-correcting circuit and the second error-correcting circuit, or reads data decoded using the linear code, when the number of fail bits in the page is equal to or higher than the predetermined value.

11. The device of claim 7, wherein
the semiconductor memory device is NAND-type EEPROM.
